(19) United States
(12) Patent Application Publication
(10) Pub. No.: US 2025/0303717 A1
(43) Pub. Date: Oct. 2, 2025

(54) LIQUID EJECTING HEAD AND LIQUID EJECTING APPARATUS

(71) Applicant: SEIKO EPSON CORPORATION, Tokyo (JP)

(72) Inventors: Motoki TAKABE, SHIOJIRI-SHI (JP); Nobuaki ITO, SUWA-SHI (JP)

(21) Appl. No.: 19/091,296

(22) Filed: Mar. 26, 2025

(30) Foreign Application Priority Data
Mar. 28, 2024 (JP) 2024-053393

(51) Int. Cl. B41J 2/14; B41J 2/045; H10N 30/00; H10N 30/853; H10N 30/87

(52) U.S. Cl. CPC B41J 2/14233; B41J 2/04581; B41J 2/04588; H10N 30/704; H10N 30/853; H10N 30/871; H10N 30/872; B41J 2002/14258

(57) ABSTRACT

A liquid ejecting head includes: a second orientation control layer for controlling an orientation of the second thin-film piezoelectric body and having a property of self-orienting itself in a predetermined plane orientation is provided between the second thin-film piezoelectric body and the individual electrode.

The present application is based on, and claims priority from JP Application Serial Number 2024-053393, filed Mar. 28, 2024, the disclosure of which is hereby incorporated by reference herein in its entirety.

### BACKGROUND

### 1. Technical Field

The present disclosure relates to a liquid ejecting head and a liquid ejecting apparatus.

### 2. Related Art

A liquid ejecting apparatus equipped with a liquid ejecting head configured to eject a liquid such as ink onto a medium such as printing paper has been proposed in the art. A piezoelectric-type ink-jet printer is known as such a liquid ejecting apparatus. A piezoelectric method uses piezoelectric elements configured to cause a diaphragm constituting a part of wall surfaces of pressure compartments to vibrate. The liquid with which the pressure comparts are filled is ejected from nozzles by causing the diaphragm to vibrate by means of the piezoelectric elements.

In a piezoelectric element included in a liquid ejecting head disclosed in JP-A-2013-256137, a first common electrode, a thin-film lower piezoelectric body layer, an individual electrode, a thin-film upper piezoelectric body layer, and a second common electrode are stacked sequentially. That is, the piezoelectric element has a structure in which two thin-film piezoelectric bodies are stacked in layers.

When thin-film piezoelectric bodies are stacked in layers as in JP-A-2013-256137, it is possible to make a displacement amount per unit voltage approximately twice as large as that of a case where a single-layer thin-film piezoelectric body is provided. Therefore, it is possible to improve ejection characteristics with the same voltage as that of a single layer or to achieve a reduction in cost by replacement with parts of lower rated voltage. However, our inventors, as a result of a further study, have discovered that more desirable effects can be obtained by setting the properties of the lower piezoelectric body and the upper piezoelectric body into appropriate values.

When a thin-film piezoelectric body is provided in the form of a single layer, it is known to use an orientation control layer for orienting the crystal of the thin-film piezoelectric body in a predetermined direction under the thin-film piezoelectric body. It is known to use a single crystal of titanium or titanium oxide as such an orientation control layer. A single crystal of titanium, and titanium oxide also, makes it possible to perform orientation control of a thin-film piezoelectric body on an orientation control layer while offering low cost.

However, in a case where a plurality of piezoelectric bodies is disposed in layers, it has been so far difficult to orient an upper piezoelectric body enough by means of an orientation control layer with a single crystal of titanium or titanium oxide. Therefore, finding a piezoelectric element with good orientation control of each of a plurality of piezoelectric bodies is awaited. The reason for the above, though uncertain, can be inferred as follows.

In a liquid ejecting head according to related art, for example, a single crystal of titanium, and titanium oxide also, reacts with an ingredient such as lead contained in a thin-film piezoelectric body to form PbTiOx, and crystal growth of the piezoelectric body occurs using it as a nucleus. However, in a case where a plurality of thin-film piezoelectric bodies is disposed in layers, when the upper piezoelectric body is formed, the ground underlying it is completely different from that of a single-layer structure of related art. This is because, probably, PbTiOx is not formed well. Moreover, even if PbTiOx can be formed well, PbTiOx itself does not have self-orientation property. For this reason, PbTiOx is influenced by each of the orientation of the lower piezoelectric body and the orientation of the individual electrode, leading to issues where the orientation of the upper piezoelectric body by PbTiOx cannot be achieved well.

### SUMMARY

A liquid ejecting head according to a certain aspect of the present disclosure includes: a pressure compartment substrate in which a plurality of pressure compartments is provided; a diaphragm; a first common electrode which is provided in common to the plurality of pressure compartments and to which a reference voltage is applied, the reference voltage being a voltage that does not vary as time progresses; a first thin-film piezoelectric body; an individual electrode which is provided individually for each of the plurality of pressure compartments and to which a drive voltage is applied, the drive voltage being a voltage that varies as time progresses; a second thin-film piezoelectric body; and a second common electrode which is provided in common to the plurality of pressure compartments and to which the reference voltage is applied, wherein the pressure compartment substrate, the diaphragm, the first common electrode, the first thin-film piezoelectric body, the individual electrode, the second thin-film piezoelectric body, and the second common electrode are stacked in this order from a lower side toward an upper side, and a second orientation control layer for controlling an orientation of the second thin-film piezoelectric body and having a property of self-orienting itself in a predetermined plane orientation is provided between the second thin-film piezoelectric body and the individual electrode.

A liquid ejecting head according to a certain aspect of the present disclosure includes: a pressure compartment substrate in which a plurality of pressure compartments is provided; a diaphragm; a first common electrode which is provided in common to the plurality of pressure compartments and to which a reference voltage is applied, the reference voltage being a voltage that does not vary as time progresses; a first thin-film piezoelectric body; an individual electrode which is provided individually for each of the plurality of pressure compartments and to which a drive voltage is applied, the drive voltage being a voltage that varies as time progresses; a second thin-film piezoelectric body; and a second common electrode which is provided in common to the plurality of pressure compartments and to which the reference voltage is applied, wherein the pressure compartment substrate, the diaphragm, the first common electrode, the first thin-film piezoelectric body, the individual electrode, the second thin-film piezoelectric body, and the second common electrode are stacked in this order from a lower side toward an upper side, and a second orientation control layer for controlling an orientation of the second thin-film piezoelectric body and being a composite oxide containing Bi, Fe, Ti, Pb and having a perovskite structure is provided between the second thin-film piezoelectric body and the individual electrode.

A liquid ejecting apparatus according to a certain aspect of the present disclosure includes: the liquid ejecting head; and a voltage application circuit for applying the reference voltage and the drive voltage.

### BRIEF DESCRIPTION OF THE DRAWINGS

FIG. 1 is a schematic diagram illustrating a configuration of a liquid ejecting apparatus according to a first embodiment.

FIG. 2 is an exploded perspective view of the liquid ejecting head illustrated in FIG. 1.

FIG. 3 is a cross-sectional view of a part of the liquid ejecting head illustrated in FIG. 2.

FIG. 4 is a cross-sectional view illustrating, in an enlarged manner, a part of the liquid ejecting head illustrated in FIG. 3.

FIG. 5 is a cross-sectional view illustrating, in an enlarged manner, a part of the liquid ejecting head illustrated in FIG. 3.

FIG. 6 is a diagram illustrating a plan-view layout of individual electrodes and a second common electrode illustrated in FIG. 4.

FIG. 7 is a diagram for explaining a drive voltage and a reference voltage.

FIG. 8 is a diagram illustrating an example of a voltage applied to a first thin-film piezoelectric body and a second thin-film piezoelectric body.

FIG. 9 is a flowchart illustrating a method of manufacturing a piezoelectric element as a part of a method of manufacturing a liquid ejecting head.

FIG. 10 is a diagram for explaining the method of manufacturing the piezoelectric element illustrated in FIG. 9.

FIG. 11 is a diagram for explaining the method of manufacturing the piezoelectric element illustrated in FIG. 9.

### DESCRIPTION OF EMBODIMENTS

With reference to the accompanying drawings, some preferred embodiments of the present disclosure will now be described. The dimensions or scales of parts illustrated in the drawings may be different from actual dimensions or scales, and some parts may be schematically illustrated for easier understanding. The scope of the present disclosure shall not be construed to be limited to these specific examples unless and except where the description below contains an explicit mention of an intent to limit the present disclosure. The phrase “equal to” as used herein encompasses the meaning of not only exact equality but also approximate equality in which a measurement error, etc. is tolerated. For a statement “an element α and an element β are stacked in layers” to hold true herein, it suffices that the element α and the element β are disposed in a vertical direction, and whether the element α and the element β are directly in contact does not matter.

The description below will be given while referring to X, Y, and Z axes intersecting with one another as needed. One direction along the X axis will be referred to as “X1 direction”. The direction that is the opposite of the X1 direction will be referred to as “X2 direction”. Directions that are the opposite of each other along the Y axis will be referred to as “Y1 direction” and “Y2 direction”. Directions that are the opposite of each other along the Z axis will be referred to as “Z1 direction” and “Z2 direction”. View in the direction along the Z axis will be referred to as “plan view”. Typically, the Z axis is a vertical axis. The Z1 direction is the direction going up. The Z2 direction is the direction going down. However, the Z axis does not necessarily have to be a vertical axis. The X, Y, and Z axes are typically orthogonal to one another, but are not limited thereto. It is sufficient as long as the X, Y, and Z axes intersect with one another within an angular range of, for example, 80° or greater and 100° or less.

### 1. First Embodiment

### 1-1. Overall Configuration of Liquid Ejecting Apparatus 100

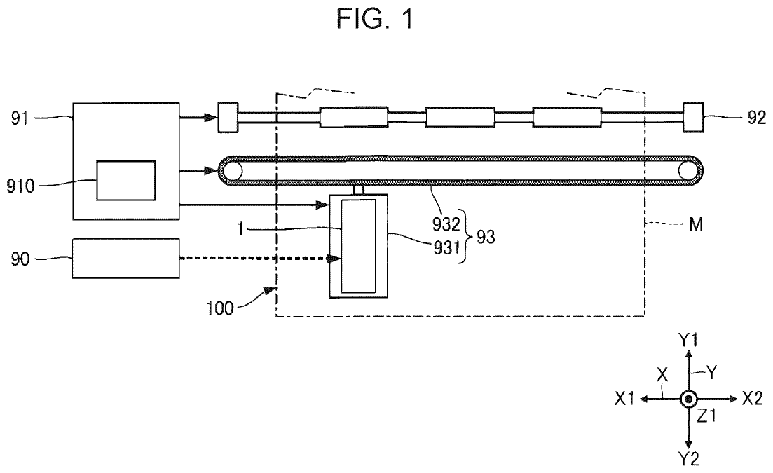

FIG. 1 is a schematic view of the configuration of a liquid ejecting apparatus 100 according to a first embodiment. The liquid ejecting apparatus 100 is an ink-jet-type printing apparatus that ejects droplets of ink, which is an example of a liquid, onto a medium M. A typical example of the medium M is printing paper. The medium M is not limited to printing paper. The medium M may be a print target made of any material such as, for example, a resin film or a cloth.

As illustrated in FIG. 1, a liquid container 90 that contains ink is attached to the liquid ejecting apparatus 100. Some specific examples of the liquid container 90 are: a cartridge that can be detachably attached to the liquid ejecting apparatus 100, a bag-type ink pack made of a flexible film material, an ink tank that can be refilled with ink, etc. Any type of ink may be contained in the liquid container 90.

The liquid ejecting apparatus 100 includes a control unit 91, a transport mechanism 92, a movement mechanism 93, and a liquid ejecting head 1. The control unit 91 includes a processing circuit, for example, a CPU (Central Processing Unit) or an FPGA (Field Programmable Gate Array), and a storage circuit such as a semiconductor memory, etc. The control unit 91 controls the operation of the elements of the liquid ejecting apparatus 100. The control unit 91 includes a voltage application circuit 910 for ejecting ink from a nozzle(s) by controlling the driving of a piezoelectric element(s) 7 to be described later. The voltage application circuit 910 applies a reference voltage VBS to be described later and a drive voltage Com to be described later to the piezoelectric element 7.

The transport mechanism 92 transports the medium M in the Y2 direction under the control of the control unit 91. The movement mechanism 93 reciprocates the liquid ejecting head 1 in the X1 direction and the X2 direction under the control of the control unit 91. In the example illustrated in FIG. 1, the movement mechanism 93 includes a box-shaped traveler 931 that is called “carriage” and houses the liquid ejecting head 1, and a transport belt 932 to which the traveler 931 is fixed. The number of the liquid ejecting head(s) 1 mounted on the traveler 931 is not limited to one. Two or more liquid ejecting heads 1 may be mounted on the traveler 931. In addition to the liquid ejecting head(s) 1, the liquid container(s) 90 may be mounted on the traveler 931.

In accordance with control by the control unit 91, the liquid ejecting head 1 ejects, from each of a plurality of nozzles toward the medium M in the Z2 direction, ink supplied from the liquid container 90. The ink is ejected in parallel with the transportation of the medium M by the transport mechanism 92 and the reciprocation of the liquid ejecting head 1 by the movement mechanism 93; as a result, an image is formed by means of ink on the surface of the medium M.

The liquid ejecting apparatus 100 described above includes the liquid ejecting head 1 to be described below and the control unit 91. The control unit 91 includes the voltage application circuit 910 for ejecting ink from nozzles N. Since the liquid ejecting apparatus 100 includes the liquid ejecting head 1 that has the features to be described later, it is possible to improve ejection performance.

### 1-2. Overall Configuration of Liquid Ejecting Head

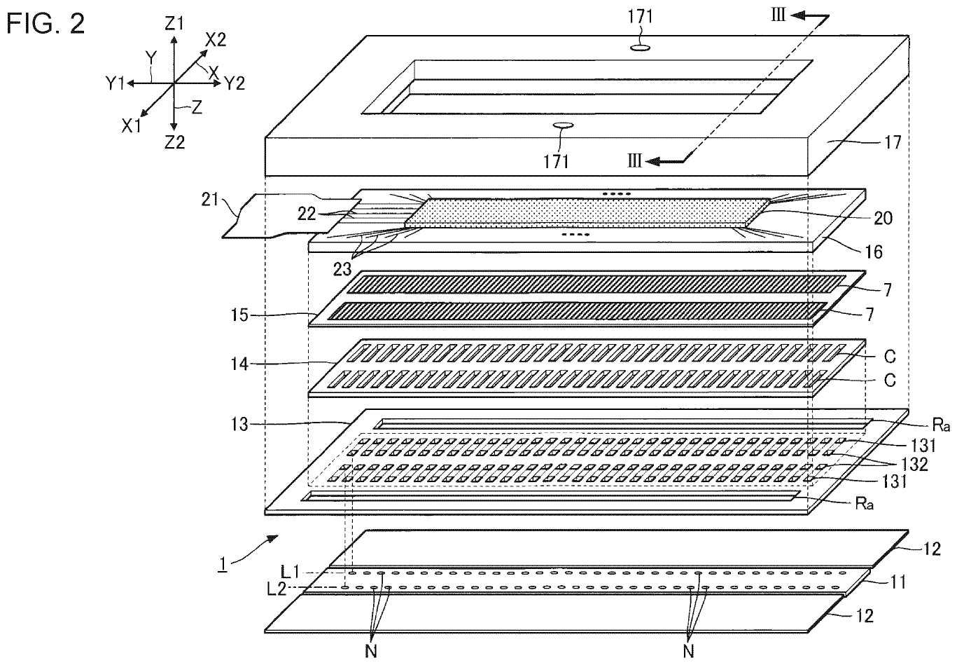

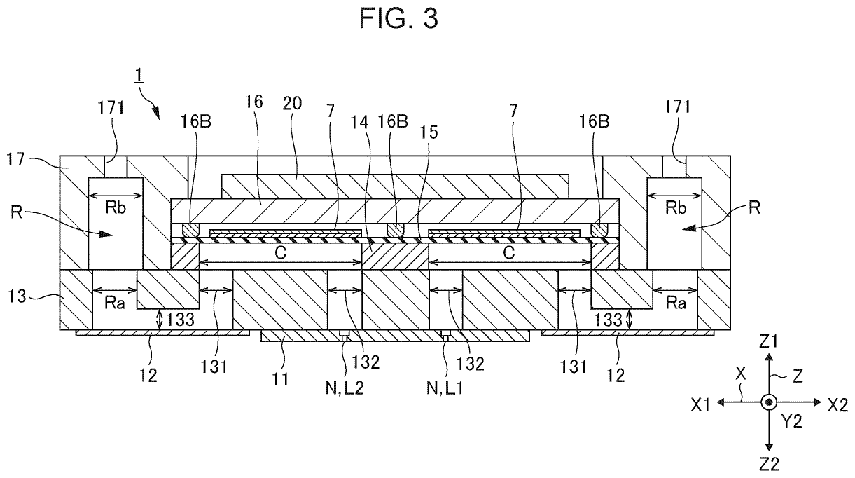

FIG. 2 is an exploded perspective view of the liquid ejecting head 1 illustrated in FIG. 1. FIG. 3 is a cross-sectional view taken along the line III-III of FIG. 2 and illustrating a part of the liquid ejecting head 1 illustrated in FIG. 2. As illustrated in FIG. 2, the liquid ejecting head 1 includes a plurality of nozzles N arranged in a direction along the Y axis. In the example illustrated in FIG. 2, the plurality of nozzles N is grouped into a first row L1 and a second row L2, which are arranged next to each other with a space in a direction along the X axis therebetween. Each of the first row L1 and the second row L2 is a group of nozzles N arranged linearly in the direction along the Y axis. In the liquid ejecting head 1, elements that are related to the nozzles N belonging to the first row L1 and elements that are related to the nozzles N belonging to the second row L2 are substantially symmetrical with each other in the direction along the X axis. In the description below, the elements corresponding to the first row L1 will be mainly explained, and an explanation of the elements corresponding to the second row L2 will be omitted where appropriate.

The positions of the plurality of nozzles N belonging to the first row L1 and the positions of the plurality of nozzles N belonging to the second row L2 may be the same as one another in the direction along the Y axis, or may be different from one another in the direction along the Y axis. Either the elements that are related to the nozzles N belonging to the first row L1 or the elements that are related to the nozzles N belonging to the second row L2 may be omitted.

As illustrated in FIGS. 2 and 3, the liquid ejecting head 1 includes a nozzle plate 11, a vibration absorber(s) 12, a flow passage substrate 13, a pressure compartment substrate 14, a diaphragm 15, a wiring substrate 16, a housing portion 17, and a drive circuit 20. Each of the nozzle plate 11, the vibration absorber 12, the flow passage substrate 13, the pressure compartment substrate 14, the diaphragm 15, the wiring substrate 16, and the housing portion 17 is a plate-like member that is elongated in the direction along the Y axis. The nozzle plate 11, the flow passage substrate 13, the pressure compartment substrate 14, the diaphragm 15, and the wiring substrate 16 are disposed in this order in the Z1 direction.

The nozzle plate 11 is a plate-like member in which the plurality of nozzles N is formed. Each of the plurality of nozzles N is a circular through hole, through which ink passes. The nozzle N ejects ink by means of the vibration of the diaphragm 15. The nozzle plate 11 is bonded to the flow passage substrate 13 using, for example, an adhesive.

Flow passages for supplying ink to the plurality of nozzles N are formed in the flow passage substrate 13. Specifically, a space(s) Ra, a plurality of supply flow passages 131, a plurality of communication flow passages 132, and a supply liquid chamber(s) 133 are formed in the flow passage substrate 13. The space Ra is an elongated opening that extends in the direction along the Y axis when viewed in plan in a direction along the Z axis. Each of the supply flow passage 131 and the communication flow passage 132 is a through hole formed individually for the nozzle N. The supply liquid chamber 133 is an elongated space extending in the direction along the Y axis throughout the plurality of nozzles N, and provides flow communication between the space Ra and the plurality of supply flow passages 131. Each of the plurality of communication flow passages 132 overlaps with the corresponding one of the nozzles N, which corresponds to this communication flow passage 132, in a plan view. The pressure compartment substrate 14 is bonded to the flow passage substrate 13 using, for example, an adhesive.

A plurality of pressure compartments C is provided in the pressure compartment substrate 14. The pressure compartments C are arranged in the direction along the Y axis. Each of the pressure compartments C is an elongated space formed individually for the corresponding one of the nozzles N and extending in the direction along the X axis in a plan view. The pressure compartment C is a space located between the flow passage substrate 13 and the diaphragm 15. The pressure compartment C is in communication with the nozzle N through the communication flow passage 132 and is in communication with the space Ra through the supply flow passage 131 and the supply liquid chamber 133.

Each of the nozzle plate 11, the flow passage substrate 13, and the pressure compartment substrate 14 is manufactured by processing a monocrystalline silicon substrate using, for example, dry etching or wet etching, etc. However, any other known method may be used for manufacturing each of the nozzle plate 11, the flow passage substrate 13, and the pressure compartment substrate 14.

The diaphragm 15 is disposed on the Z1-side surface of the pressure compartment substrate 14. The diaphragm 15 is a plate-like member that is able to elastically vibrate.

The plurality of piezoelectric elements 7 corresponding to the nozzles N is disposed on the Z1-side surface of the diaphragm 15. Each of the plurality of piezoelectric elements 7 has an elongated shape extending in the direction along the X axis in a plan view. The plurality of piezoelectric elements 7 corresponds to the plurality of pressure compartments C and is arranged in the direction along the Y axis. The piezoelectric element 7 deforms in response to voltage application. When the diaphragm 15 vibrates by being driven by this deformation, the vibration causes a change in pressure inside the pressure compartment C, and, as a result, ink is ejected from the nozzle N.

The housing portion 17 is a case for temporarily containing ink that is to be supplied to the plurality of pressure compartments C. As illustrated in FIG. 3, a space(s) Rb is formed in the housing portion 17. The space Rb of the housing portion 17 and the space Ra of the flow passage substrate 13 are in communication with each other. A combined space made up of the space Ra and the space Rb serves as a liquid pooling chamber R, which is a reservoir for temporarily containing ink that is to be supplied to the plurality of pressure compartments C. Ink is supplied to the liquid pooling chamber R through an inlet 171 formed through the housing portion 17. The ink present inside the liquid pooling chamber R is supplied to each pressure compartment C through the supply liquid chamber 133 and the corresponding supply flow passage 131.

The vibration absorber 12 is a flexible film that constitutes a wall surface of the liquid pooling chamber R. The vibration absorber 12 is a compliance substrate that absorbs changes in pressure of the ink inside the liquid pooling chamber R.

The wiring substrate 16 is a plate-like member on which wiring for electric connection between the drive circuit 20 and the plurality of piezoelectric elements 7 is formed. The Z2-side surface of the wiring substrate 16 is bonded to the diaphragm 15, with a plurality of conductive bumps 16B provided therebetween. The drive circuit 20 is mounted on the Z1-side surface of the wiring substrate 16. The drive circuit 20 is an IC (Integrated Circuit) chip that outputs the reference voltage VBS and the drive voltage Com for driving each of the plurality of piezoelectric elements 7.

As illustrated in FIG. 2, an end portion of external wiring 21 is connected to the Z1-side surface of the wiring substrate 16. The external wiring 21 is made of a connection part such as, for example, an FPC (Flexible Printed Circuit) or an FFC (Flexible Flat Cable). A plurality of wiring lines 22 for electric connection between the external wiring 21 and the drive circuit 20, and a plurality of wiring lines 23 via which the reference voltage VBS and the drive voltage Com outputted from the drive circuit 20 are supplied, are formed on the wiring substrate 16.

The wiring substrate 16 is not limited to a rigid substrate; for example, it may be an FPC (Flexible Printed Circuit) or an FFC (Flexible Flat Cable). In this case, the wiring substrate 16 may serve also as the external wiring 21.

### 1-3. Diaphragm 15

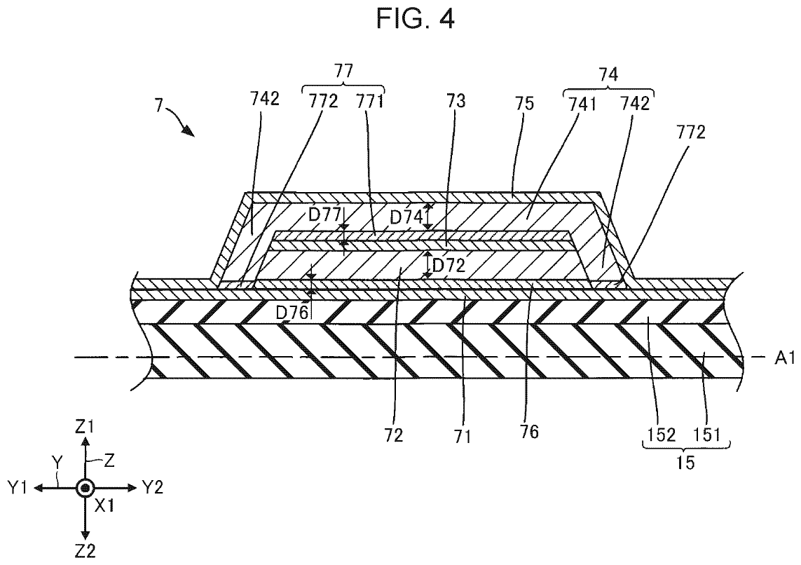

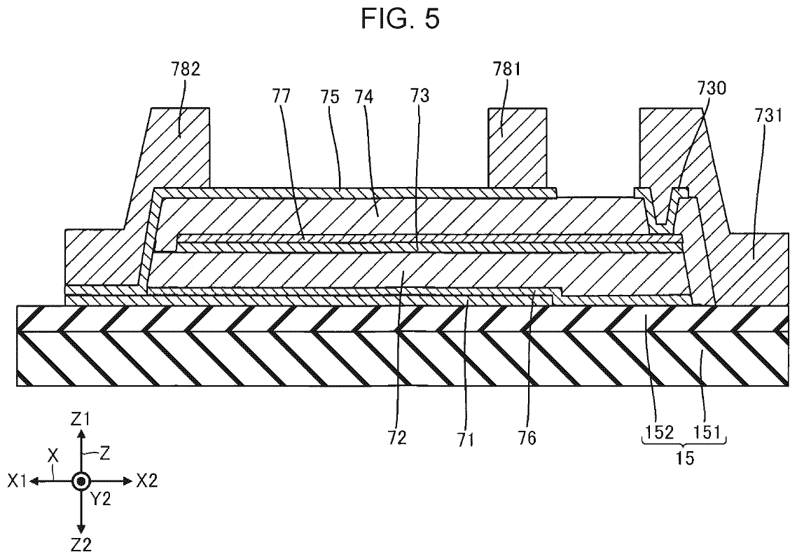

Each of FIGS. 4 and 5 is a cross-sectional view illustrating, in an enlarged manner, a part of the liquid ejecting head 1 illustrated in FIG. 3. The diaphragm 15 illustrated in FIGS. 4 and 5 vibrates in accordance with the vibration of the piezoelectric element 7. The diaphragm 15 includes, for example, a first layer 151 and a second layer 152. The first layer 151 and the second layer 152 are stacked in this order from the lower side toward the upper side, that is, in the Z1 direction.

The first layer 151 is, for example, an elastic film made of silicon oxide (SiO₂). The elastic film is formed by, for example, thermally oxidizing one surface of a monocrystalline silicon substrate. The second layer 152 is, for example, an insulating film made of zirconium oxide (ZrO₂). The insulating film is formed by, for example, producing a zirconium layer by sputtering and next thermally oxidizing the zirconium layer. Zirconium oxide has excellent electric insulating property, mechanical strength, and toughness. Since the diaphragm 15 includes the second layer 152 containing zirconium oxide having these features, it is possible to enhance the characteristics of the diaphragm 15.

Another layer such as a layer of metal oxide, etc. may be provided between the first layer 151 and the second layer 152. A part or a whole of the diaphragm 15 may be formed integrally with the pressure compartment substrate 14. The diaphragm 15 may be configured as a layer of a single material. In FIG. 4, a neutral axis A1 of the diaphragm 15 is illustrated.

### 1-4. Piezoelectric Element 7

As illustrated in FIG. 3, the piezoelectric element 7 overlaps with the pressure compartment C described earlier in a plan view. As illustrated in FIGS. 4 and 5, the piezoelectric element 7 is disposed on the diaphragm 15. The piezoelectric element 7 includes a first common electrode 71, a first orientation control layer 76, a first thin-film piezoelectric body 72, an individual electrode 73, a second orientation control layer 77, a second thin-film piezoelectric body 74, and a second common electrode 75. Among them, roughly speaking, the first common electrode 71 and the second common electrode 75 are common to the plurality of piezoelectric elements 7. The first thin-film piezoelectric body 72 and the second thin-film piezoelectric body 74 are each split between the plurality of piezoelectric elements 7 by through holes H0 to be described later in a range of overlapping with the pressure compartments C in a plan view taken in the direction along the Z axis, but are configured as a single stretch of member that is continuous in a range of not overlapping with the pressure compartments C. However, the first thin-film piezoelectric body 72 and the second thin-film piezoelectric body 74 do not necessarily have to be configured as such a continuous stretch of member. The individual electrode 73 is provided individually for each of the piezoelectric elements 7. The pressure compartment substrate 14 described earlier, the diaphragm 15, the first common electrode 71, the first thin-film piezoelectric body 72, the individual electrode 73, the second thin-film piezoelectric body 74, and the second common electrode 75 are stacked in this order from the lower side toward the upper side. The first orientation control layer 76 is provided between the first thin-film piezoelectric body 72 and the first common electrode 71. The second orientation control layer 77 is provided between the second thin-film piezoelectric body 74 and the individual electrode 73. Another layer such as a layer for enhancing adhesion, etc. may be provided between one layer and another layer of the piezoelectric element 7, or between the piezoelectric element 7 and the diaphragm 15.

1-4a. First Common Electrode 71

The first common electrode 71 is provided in common to the plurality of pressure compartments C described earlier. The first common electrode 71 has a band-like shape extending in the direction along the Y axis continuously throughout the plurality of pressure compartments C. The reference voltage VBS, which does not vary as time progresses, is applied to the first common electrode 71.

The material of the first common electrode 71 is, for example, metal such as platinum (Pt), iridium (Ir), aluminum (Al), nickel (Ni), gold (Au), copper (Cu), or the like, or alloy thereof or the like. The first common electrode 71 may be a single-layer electrode or a multiple-layer electrode. For example, the first common electrode 71 has a layered structure including a platinum layer stacked on an iridium layer.

1-4b. Individual Electrode 73

The individual electrode 73 is provided individually for each of the plurality of pressure compartments C. The drive voltage Com, which varies as time progresses, is applied to the individual electrode 73.

The material of the individual electrode 73 is, for example, metal such as platinum, iridium, aluminum, nickel, gold, copper, or the like, or alloy thereof or the like. The individual electrode 73 may be a single-layer electrode or a multiple-layer electrode.

1-4c. Second Common Electrode 75

The second common electrode 75 is provided in common to the plurality of pressure compartments C described earlier. The second common electrode 75 has a band-like shape extending in the direction along the Y axis continuously throughout the plurality of pressure compartments C. The reference voltage VBS, which does not vary as time progresses, is applied to the second common electrode 75. Therefore, a common potential is applied to the first common electrode 71 and the second common electrode 75.

The material of the second common electrode 75 is, for example, metal such as platinum, iridium, aluminum, nickel, gold, copper, or the like, or alloy thereof or the like. The second common electrode 75 may be a single-layer electrode or a multiple-layer electrode.

As illustrated in FIG. 5, two conductors 781 and 782 are disposed on the second common electrode 75. Each of the conductors 781 and 782 is a band-like conductive film extending in the direction along the Y axis alongside of an X1-side edge or an X2-side edge of the second common electrode 75. The conductors 781 and 782 are made of, for example, a conductive material that has an electrically low resistance such as gold. A drop in the reference voltage VBS at the second common electrode 75 is suppressed by the conductors 781 and 782. The conductors 781 and 782 serve also as weights that define a vibration region of the diaphragm 15. The conductors 781 and 782 may be omitted.

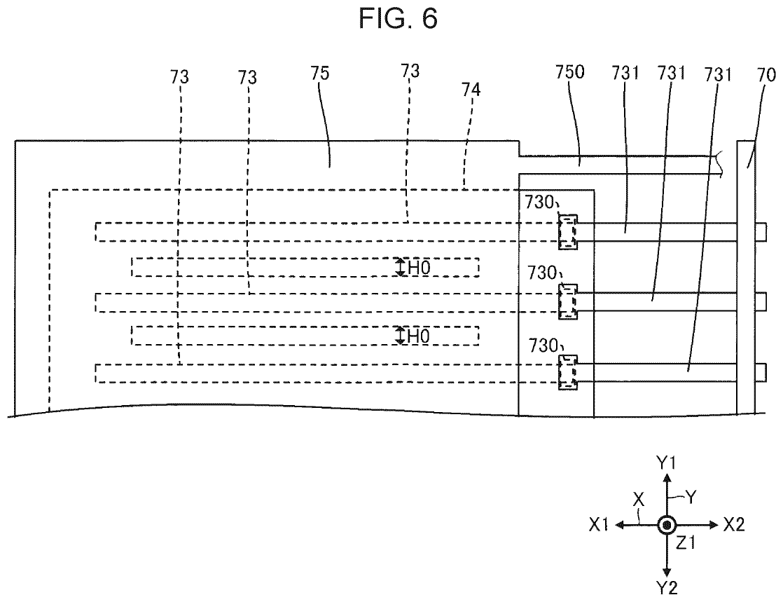

FIG. 6 is a diagram illustrating a plan-view layout of the individual electrodes 73 and the second common electrode 75 illustrated in FIG. 4. As illustrated in FIG. 6, each of the individual electrodes 73 is an elongated electrode extending along the X axis. The individual electrodes 73 are spaced apart from one another and are arranged along the Y axis. As illustrated in FIGS. 5 and 6, one end in the longer-side direction along the X axis of each of the individual electrodes 73 is connected to a lead wiring line 731 via a connection wiring line 730. The lead wiring lines 731 are connected to a wiring line 70 extending along the Y axis. The wiring line 70 is electrically coupled to the drive circuit 20, which is mounted on the wiring substrate 16, via the plurality of conductive bumps 16B described earlier. Though detailed illustration is omitted, the first common electrode 71 is electrically coupled to the drive circuit 20, which is mounted on the wiring substrate 16, via the plurality of conductive bumps 16B described earlier, similarly to the second common electrode 75.

The second common electrode 75 overlaps with the plurality of individual electrodes 73 in a plan view. Though detailed illustration is omitted, the first common electrode 71 overlaps with the plurality of individual electrodes 73 in a plan view. As described earlier, the second common electrode 75 has a band-like shape extending in the direction along the Y axis, for example, a rectangular shape. A lead wiring line 750 is connected to a corner portion of the second common electrode 75. The lead wiring line 750 is electrically coupled to the drive circuit 20, which is mounted on the wiring substrate 16, via the plurality of conductive bumps 16B described earlier. Therefore, the second common electrode 75 is electrically coupled to the drive circuit 20. On the other hand, the first common electrode 71 is in contact with the second common electrode 75 at regions of not overlapping with the pressure compartments C in a plan view taken in the direction along the Z axis, as illustrated at a Y1-side end portion and a Y2-side end portion in FIG. 4 and at an X1-side lateral end portion in FIG. 5. Because of this contact, the first common electrode 71 and the second common electrode 75 are at the same potential. In other words, the first common electrode 71 is electrically coupled to the drive circuit 20 via the second common electrode 75. Though the first common electrode 71 and the second common electrode 75 are physically in contact with each other in the present embodiment, any other member may be interposed therebetween as long as they are electrically coupled.

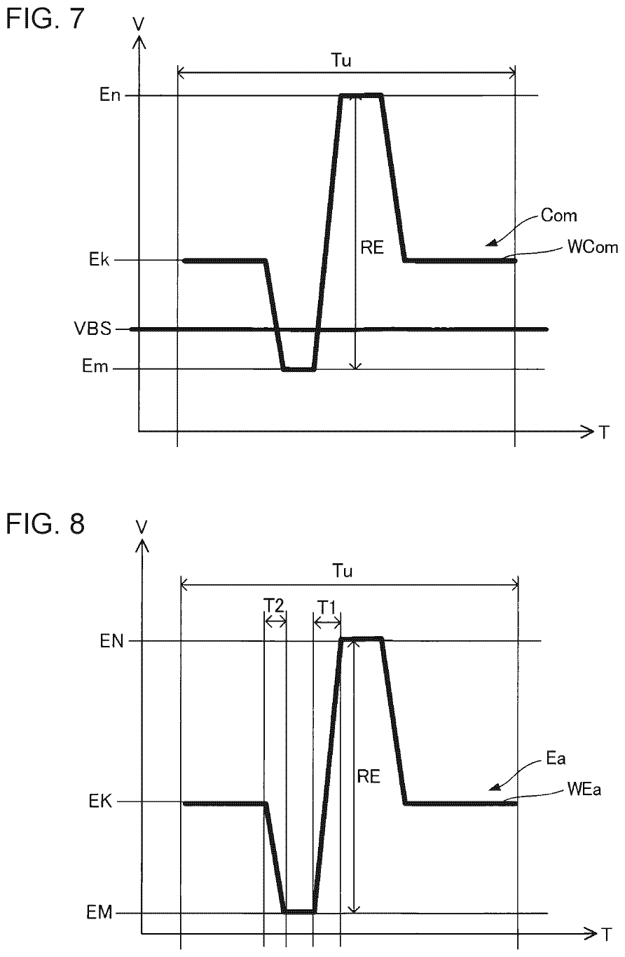

FIG. 7 is a diagram for explaining the drive voltage Com and the reference voltage VBS. In FIG. 7, the horizontal axis represents time, and the vertical axis represents voltage [V].

A voltage is applied to the piezoelectric element 7 by the voltage application circuit 910 described earlier. Specifically, the voltage application circuit 910 applies a voltage to the first thin-film piezoelectric body 72 via the first common electrode 71 and the individual electrode 73. The first thin-film piezoelectric body 72 deforms in accordance with the voltage applied between the first common electrode 71 and the individual electrode 73. Similarly, the voltage application circuit 910 applies a voltage to the second thin-film piezoelectric body 74 via the second common electrode 75 and the individual electrode 73. The second thin-film piezoelectric body 74 deforms in accordance with the voltage applied between the second common electrode 75 and the individual electrode 73.

The drive voltage Com, which is dependent on an amount of ink to be ejected, is applied to the individual electrode 73. The drive voltage Com varies as time progresses. The drive voltage Com has a drive waveform Wcom. The drive waveform Wcom is repeated in a cycle of a unit period Tu. The drive waveform Wcom includes an intermediate voltage Ek, a maximum voltage En, and a minimum voltage Em. The maximum voltage En is the maximum value of the drive voltage Com. The minimum voltage Em is the minimum value of the drive voltage Com. The drive waveform Wcom falls from the intermediate voltage Ek to the minimum voltage Em, rises from the minimum voltage Em to the maximum voltage En after keeping its level at the minimum voltage Em, and falls from the maximum voltage En to the intermediate voltage Ek after keeping its level at the maximum voltage En. Note that the drive waveform Wcom illustrated in FIG. 7 is just an example. The drive voltage Com may have any other waveform.

The reference voltage VBS, which is constant irrespective of an amount of ink to be ejected, is applied to the first common electrode 71 and the second common electrode 75. The reference voltage VBS does not vary as time progresses, meaning a constant level. In the illustrated example, the value of the reference voltage VBS is above the minimum voltage Em of the drive voltage Com. However, this does not imply any limitation. The reference voltage VBS may be a GND potential, that is, 0 V.

FIG. 8 is a diagram illustrating an example of a voltage Ea applied to the first thin-film piezoelectric body 72 and the second thin-film piezoelectric body 74. The applied voltage Ea illustrated in FIG. 8 is obtained by subtracting the reference voltage VBS from the drive voltage Com illustrated in FIG. 7 at each point in time.

Due to the applying of the drive voltage Com and the reference voltage VBS, a voltage corresponding to a difference between the drive voltage Com and the reference voltage VBS is applied between the first common electrode 71 and the individual electrode 73 to the first thin-film piezoelectric body 72, and, as a result, the first thin-film piezoelectric body 72 deforms. Similarly, due to the applying of the drive voltage Com and the reference voltage VBS, a voltage corresponding to a difference between the drive voltage Com and the reference voltage VBS is applied between the second common electrode 75 and the individual electrode 73 to the second thin-film piezoelectric body 74, and, as a result, the second thin-film piezoelectric body 74 deforms.

In FIG. 8, the horizontal axis represents time, and the vertical axis represents voltage [V]. The applied voltage Ea has a waveform WEa. The waveform WEa includes an intermediate voltage EK, a maximum voltage EN, and a minimum voltage EM. The maximum voltage EN is a difference between the maximum voltage En of the drive voltage Com and the reference voltage VBS. The minimum voltage EM is a difference between the minimum voltage Em of the drive voltage Com and the reference voltage VBS. Note that the waveform WEa illustrated in FIG. 8 is just an example. It differs depending on the drive voltage Com and the reference voltage VBS.

Since the reference voltage VBS is constant, a voltage range RE of the applied voltage Ea is equal to a voltage range RE of the drive voltage Com.

### 1-4D. First Thin-Film Piezoelectric Body 72 and Second Thin-Film Piezoelectric Body 74

As described earlier, the first thin-film piezoelectric body 72 is disposed between the first common electrode 71 and the individual electrode 73, and deforms in accordance with a potential difference between the first common electrode 71 and the individual electrode 73.

The first thin-film piezoelectric body 72 illustrated in FIGS. 4 and 5 is made of a composite oxide. The first orientation control layer 76 is disposed beneath the first thin-film piezoelectric body 72. The first thin-film piezoelectric body 72 is orientation-controlled by the first orientation control layer 76.

The first thin-film piezoelectric body 72 includes an active portion and an inactive portion. The active portion is a portion, of the first thin-film piezoelectric body 72, located between the first common electrode 71 and the individual electrode 73. The inactive portion is a portion thereof not located between the first common electrode 71 and the individual electrode 73.

As described earlier, the second thin-film piezoelectric body 74 is disposed between the second common electrode 75 and the individual electrode 73, and deforms in accordance with a potential difference between the second common electrode 75 and the individual electrode 73.

The second thin-film piezoelectric body 74 is made of a composite oxide. The second orientation control layer 77 is disposed beneath the second thin-film piezoelectric body 74. The second thin-film piezoelectric body 74 is orientation-controlled by the second orientation control layer 77 disposed beneath it.

As illustrated in FIG. 6, the second thin-film piezoelectric body 74 has a band-like shape extending along the Y axis. The through holes H0 are provided in the second thin-film piezoelectric body 74 each at a region corresponding to, in a plan view, each gap between the pressure compartments C located adjacent to one another. The second thin-film piezoelectric body 74 is separated by the through holes H0 individually for the pressure compartments C. Though detailed illustration is omitted, the first thin-film piezoelectric body 72 described above also has through holes that are similar to the through holes H0 of the second thin-film piezoelectric body 74, and is thus separated individually for the pressure compartments C.

As illustrated in FIG. 5, the second thin-film piezoelectric body 74 includes an active portion 741 and an inactive portion 742. The active portion 741 is a portion located between the individual electrode 73 and the second common electrode 75. The active portion 741 is located right above the first thin-film piezoelectric body 72, and overlaps with the first thin-film piezoelectric body 72 in a plan view. The inactive portion 742 is a portion not located between the individual electrode 73 and the second common electrode 75. The inactive portion 742 extends outside the first thin-film piezoelectric body 72.

Each of the first thin-film piezoelectric body 72 and the second thin-film piezoelectric body 74 is made of a composite oxide as described earlier. Specifically, each of the first thin-film piezoelectric body 72 and the second thin-film piezoelectric body 74 is made of a piezoelectric material that has a perovskite-type crystal structure.

Examples of such a piezoelectric material include, for example, lead titanate (PbTiO₃), lead zirconate titanate (PZT: Pb(Zr,Ti)O₃), lead zirconate (PbZrO₃), lead lanthanum titanate ((Pb,La),TiO₃), lead lanthanum zirconate titanate ((Pb,La)(Zr, Ti)O₃), lead niobate zirconate titanate (Pb(Zr,Ti,Nb)O₃), lead magnesium niobate zirconate titanate (Pb(Zr,Ti)(Mg,Nb)O₃), and the like. Among them, lead zirconate titanate (PZT) can be suitably used as the material of the thin-film piezoelectric body. The thin-film piezoelectric body may contain a small amount of another element such as impurity. Each of the first thin-film piezoelectric body 72 and the second thin-film piezoelectric body 74 may have a single-layer structure or a multiple-layer structure.

The material of the first thin-film piezoelectric body 72 and the material of the second thin-film piezoelectric body 74 may be the same as each other; however, the material of the former and the material of the latter may preferably be different from each other. Desirable properties for the first thin-film piezoelectric body 72 and desirable properties for the second thin-film piezoelectric body 74 could differ from each other depending on what sort of the piezoelectric element 7 is intended. Therefore, if the same material is used for the first thin-film piezoelectric body 72 and the second thin-film piezoelectric body 74, the degree of freedom in design decreases, making it difficult to obtain optimal properties for each of the first thin-film piezoelectric body 72 and the second thin-film piezoelectric body 74. Using materials different from each other for the first thin-film piezoelectric body 72 and the second thin-film piezoelectric body 74 makes it possible to design each of the first thin-film piezoelectric body 72 and the second thin-film piezoelectric body 74 with optimal properties. Therefore, it is possible to configure the piezoelectric element 7 as desired.

The material of the first thin-film piezoelectric body 72 and the material of the second thin-film piezoelectric body 74, when looked at from another perspective, may preferably be the same as each other. Using the same material for the first thin-film piezoelectric body 72 and the second thin-film piezoelectric body 74 makes manufacturing easier. For example, this makes it easier to design desired properties just through film-thickness control.

Each of the first thin-film piezoelectric body 72 and the second thin-film piezoelectric body 74 is a thin film. Specifically, the term “thin film” in the present embodiment means a thickness of at most 5 μm or less, or more preferably, 2 μm or less. The thickness of the first thin-film piezoelectric body 72 and the thickness of the second thin-film piezoelectric body 74 may be the same as each other or different from each other.

The piezoelectric element 7, which includes the first thin-film piezoelectric body 72 and the second thin-film piezoelectric body 74 described above, deforms in such a way as to cause flexion of the piezoelectric element 7 and the diaphragm 15 in the Z1 direction in an expansion period T2, which is a period of causing the pressure compartment C to expand by lowering the voltage from the intermediate voltage EK to the minimum voltage EM in FIG. 8. That is, the piezoelectric element 7 deforms upward in such a way as to cause the pressure compartment C to expand. As a result of this expansive deformation, ink is taken into the pressure compartment C. Next, deformation occurs in such a way as to cause flexion of the piezoelectric element 7 and the diaphragm 15 in the Z2 direction in a contraction period T1, which is a period of causing the pressure compartment C to contract by raising the voltage from the minimum voltage EM to the maximum voltage EN. That is, the piezoelectric element 7 deforms downward in such a way as to cause the pressure compartment C to contract. As a result of this contractive deformation, the ink present inside the pressure compartment C is ejected.

### 1-4E. First Orientation Control Layer 76 and Second Orientation Control Layer 77

As illustrated in FIGS. 4 and 5, the first orientation control layer 76 is provided between the first thin-film piezoelectric body 72 and the first common electrode 71. The second orientation control layer 77 is provided between the second thin-film piezoelectric body 74 and the individual electrode 73. The first orientation control layer 76 controls the orientation of the first thin-film piezoelectric body 72. The second orientation control layer 77 controls the orientation of the second thin-film piezoelectric body 74.

Since the first orientation control layer 76 and the second orientation control layer 77 are provided, it is possible to control the orientation of each of the first thin-film piezoelectric body 72 and the second thin-film piezoelectric body 74. That is, it is possible to preferentially orient the crystal of the first thin-film piezoelectric body 72 into a predetermined plane orientation and to adjust the orientation degree of the predetermined plane orientation by means of the first orientation control layer 76. Similarly, it is possible to preferentially orient the crystal of the second thin-film piezoelectric body 74 into a predetermined plane orientation and to adjust the orientation degree of the predetermined plane orientation by means of the second orientation control layer 77.

For example, by preferentially orienting the crystal of the first thin-film piezoelectric body 72 in a (100) plane by means of the first orientation control layer 76, as compared with a case where the crystal is preferentially oriented in a (110) plane, it is possible to improve the piezoelectric characteristics of the piezoelectric element 7. Similarly, by preferentially orienting the crystal of the second thin-film piezoelectric body 74 in a (100) plane by means of the second orientation control layer 77, as compared with a case where the crystal is preferentially oriented in a (110) plane, it is possible to improve the piezoelectric characteristics of the piezoelectric element 7. Therefore, it is possible to enhance the displacement efficiency of the piezoelectric element 7.

Moreover, for example, the first orientation control layer 76 is capable of adjusting the orientation degree of the crystal of the first thin-film piezoelectric body 72 in a (100) plane. Similarly, the second orientation control layer 77 is capable of adjusting the orientation degree of the crystal of the second thin-film piezoelectric body 74 in the (100) plane. Therefore, providing the first orientation control layer 76 configured to control the orientation of the first thin-film piezoelectric body 72 and providing the second orientation control layer 77 configured to control the orientation of the second thin-film piezoelectric body 74 makes it possible to adjust the orientation degree of each of the first thin-film piezoelectric body 72 and the second thin-film piezoelectric body 74 into a desired orientation degree. Therefore, it is possible to set optimal properties for each of the first thin-film piezoelectric body 72 and the second thin-film piezoelectric body 74.

An X-ray diffraction intensity curve of an X-ray diffraction (XRD) method can be analyzed for crystal orientation. “Preferentially oriented in a (100) plane” means that a peak intensity corresponding to a (100) plane is higher than that of other directions, specifically, a peak intensity corresponding to a (110) plane. In particular, it is possible to enhance the displacement efficiency of the piezoelectric element 7 by orienting 50% or greater, or 80% or greater, of the crystal of the thin-film piezoelectric body in a (100) plane.

In related art, when a thin-film piezoelectric body is provided in the form of a single layer, it is known to use an orientation control layer for orienting the crystal of the thin-film piezoelectric body in a predetermined direction under the thin-film piezoelectric body. It is known to use a single crystal of titanium or titanium oxide as such an orientation control layer. A single crystal of titanium, and titanium oxide also, makes it possible to perform orientation control of a thin-film piezoelectric body on an orientation control layer while offering low cost.

However, in a case where a plurality of thin-film piezoelectric bodies is disposed in layers as in the present embodiment, it has been so far difficult to orient the second thin-film piezoelectric body 74 enough if the second orientation control layer 77 is configured as a layer that includes a single crystal of titanium or a layer that includes titanium oxide. The reason, though uncertain, can be inferred as follows.

A single crystal of titanium, and titanium oxide also, reacts with an ingredient such as lead contained in a thin-film piezoelectric body to form PbTiOx, and crystal growth of the first thin-film piezoelectric body occurs using it as a nucleus. However, in a structure in which a plurality of thin-film piezoelectric bodies is stacked as in the present embodiment, the ground underlying the second thin-film piezoelectric body 74 is completely different from the ground underlying the first thin-film piezoelectric body 72, and from the ground underlying the single-layer thin-film piezoelectric body of related art.

As illustrated in FIG. 4, the second orientation control layer 77 includes a first portion 771 and a second portion 772. The first portion 771 is disposed right above the individual electrode 73 and is in contact with the individual electrodes 73. The active portion 741 of the second thin-film piezoelectric body 74 is provided on the first portion 771. The second portion 772 is disposed on the first common electrode 71 and is in contact with the first common electrode 71. The second portion 772 does not overlap with the individual electrode 73 in a plan view.

As described above, the ground underlying the second orientation control layer 77 is not uniform and includes different portions. That is, the second orientation control layer 77 is in contact with two or more different layers. Furthermore, the first thin-film piezoelectric body 72 exists as the layer underlying the individual electrode 73. For example, if the direction of preferential orientation of the individual electrode 73 and the direction of preferential orientation of the first thin-film piezoelectric body 72 are different from each other, the second orientation control layer 77 is further influenced by this difference between these directions. As explained above, the ground underlying the second orientation control layer 77 is complex. This is the plausible reason why it is difficult to form PbTiOx well due to the influence of the underlying ground in related art.

Moreover, even if PbTiOx can be formed well, PbTiOx itself does not have self-orientation property. For this reason, PbTiOx is influenced by each orientation of the individual electrode 73, etc., leading to issues where the orientation of the second thin-film piezoelectric body 74 by PbTiOx cannot be achieved well.

In view of this, in the present embodiment, the second orientation control layer 77 has self-orientation property, which is property of orienting itself into a predetermined plane orientation. Therefore, the second orientation control layer 77 is configured to not only preferentially orient the second thin-film piezoelectric body 74 into a predetermined plane orientation but also preferentially orient itself into the predetermined plane orientation. For this reason, even in a case where the underlying ground is complex as described above, since the second orientation control layer 77 has self-orientation property, the second orientation control layer 77 orients itself into the predetermined plane orientation without being influenced by the underlying ground. Therefore, it is possible to preferentially orient the second thin-film piezoelectric body 74 into the predetermined plane orientation without being influenced by the above-described complex ground underlying it.

Specifically, for example, the second orientation control layer 77 is self-oriented in the (100) plane. Due to the influence of the orientation of the second orientation control layer 77, the second thin-film piezoelectric body 74 is preferentially oriented in the same plane orientation as that of the second orientation control layer 77. Therefore, the second orientation control layer 77 preferentially orients itself into the (100) plane; in addition, the second orientation control layer 77 preferentially orients the second thin-film piezoelectric body 74 into the (100) plane.

Since the second orientation control layer 77 preferentially orients the crystal of the second thin-film piezoelectric body 74 in the (100) plane, as compared with a case where the crystal is preferentially oriented in the (110) plane, it is possible to improve the piezoelectric characteristics of the piezoelectric element 7. Therefore, it is possible to enhance the displacement efficiency of the piezoelectric element 7.

The individual electrode 73, which is the ground underlying the second orientation control layer 77, is, for example, preferentially oriented in the (111) plane. In this case, the individual electrode 73 and the second orientation control layer 77 are preferentially oriented in plane orientations different from each other. Suppose that the second orientation control layer 77 does not have self-orientation property; if so, the second orientation control layer 77 is influenced by the plane orientation of the individual electrode 73 and therefore might be preferentially oriented in the same plane orientation as that of the individual electrode 73. In this respect, however, the second orientation control layer 77 according to the present embodiment has self-orientation property. Therefore, the second orientation control layer 77 self-orients itself in a predetermined plane orientation, specifically, the (100) plane, without being influenced by the plane orientation of the individual electrode 73, which is the ground underlying it. For this reason, the second orientation control layer 77 is capable of preferentially orienting the second thin-film piezoelectric body 74 in a predetermined plane orientation, specifically, the (100) plane, without being affected by the underlying influence.

Furthermore, for example, the first thin-film piezoelectric body 72, which is the layer underlying the individual electrode 73, is preferentially oriented in the (100) plane. In this case, the plane orientation of the first thin-film piezoelectric body 72 is different from that of the individual electrode 73. In a case where the layers that underlie the second orientation control layer 77 constitute a layered structure with a plurality of plane orientations different from each other as in this example, if the second orientation control layer 77 does not have self-orientation property, the second orientation control layer 77 is influenced by the layered structure. The complexity of the influence on the second orientation control layer 77 increases if the layers that constitute the layered structure with the plurality of plane orientations different from each other exist under it.

However, the second orientation control layer 77 according to the present embodiment has self-orientation property and thus self-orients itself in a predetermined plane orientation. Therefore, the second orientation control layer 77, even in a case where a complex layered structure exists under it, is capable of preferentially orienting the second thin-film piezoelectric body 74 in a predetermined plane orientation, specifically, the (100) plane, without being affected by the underlying influence.

It is preferable if the second orientation control layer 77 is a composite oxide containing La, Ni and having a perovskite structure. Specifically, for example, it is preferable if the second orientation control layer 77 is made of LaNiOₓ. If the second orientation control layer 77 is made of LaNiOₓ, the second orientation control layer 77 having self-orientation property is realized.

It is preferable if the second orientation control layer 77 is a composite oxide containing Fe, Ti, Pb and having a perovskite structure. Specifically, for example, it is preferable if the second orientation control layer 77 is made of PbₓFe_{y}Ti_{(1-y)}O_{z}.

In PbₓFe_{y}T_{i(1-y)}O_{z}, x satisfies a relation of 1.00≤x<2.00. For orientation in a (100) plane, it is preferable if x satisfies a relation of 1.00≤x<1.50. y satisfies a relation of 0.10≤y≤0.90. For orientation in a (100) plane, it is preferable if y satisfies a relation of 0.20≤y≤0.80. Typically, z satisfies a relation of z=3.00. However, z does not necessarily have to satisfy this relation. In the description below, PbₓFe_{y}Ti_{(1-y)}O_{z} will be simply referred to as “PbFeTiO”.

If the second orientation control layer 77 is made of PbFeTiO, the second orientation control layer 77 having self-orientation property is realized. The second orientation control layer 77 made of PbFeTiO is more stable than the second orientation control layer 77 made of LaNiOₓ. Therefore, it is possible to suppress a decrease in piezoelectric characteristics of the second thin-film piezoelectric body 74 due to the diffusion of the ingredients of the second orientation control layer 77 into the second thin-film piezoelectric body 74.

It is more preferable if the second orientation control layer 77 is a composite oxide containing Bi, Fe, Ti, Pb and having a perovskite structure. Specifically, for example, it is preferable if the second orientation control layer 77 is PbₓBi₍ₐ₋ₓ₎Fe_{y}Ti_{(b-y)}O_{z}.

In PbₓBᵢ₍ₐ₋ₓ₎Fe_{y}Ti_{(b-y)}O_{z}, a>x, and b>y. It is preferable if x(a−x) satisfies: 0.04<x(a−x)<1.40. Moreover, for orientation in a (100) plane, it is more preferable if x(a−x)<0.72. It is preferable if b=1, and it is preferable if a/b satisfies: 0.8<(a/b)<1.4. It is preferable if z satisfies: 2.8<z<3.2.

An example of values satisfying these preferred ranges is a=1.2, b=1.0, x=0.1, and y=0.5. In the description below, PbₓBᵢ₍ₐ₋ₓ₎Fe_{y}Ti_{(b-y)}O_{z} will be simply referred to as “PbBiFeTiO”.

If the second orientation control layer 77 is made of PbBiFeTiO, the second orientation control layer 77 having self-orientation property is realized. The second orientation control layer 77, if made of PbBiFeTiO, is less susceptible to the influence of the ground underlying it as compared with a case where it is made of LaNiOₓ or PbFeTiO, even if the ground has a complex structure. Therefore, it is easier to increase the degree of orientation in a predetermined plane orientation of the second thin-film piezoelectric body 74. Specifically, for example, it is possible to increase the degree of orientation in the (100) plane of the second thin-film piezoelectric body 74.

The second orientation control layer 77 has self-orientation property, and the first orientation control layer 76 may have self-orientation property of self-orienting itself in a predetermined plane orientation or may have a property of not self-orienting itself in a predetermined plane orientation.

The ground underlying the first orientation control layer 76 is the first common electrode 71, which is provided uniformly in common to the plurality of pressure compartments C. Therefore, the structure of the ground underlying the first orientation control layer 76 is less complex than that of the second orientation control layer 77. For this reason, even in a case where the first orientation control layer 76 does not have self-orientation property, the possibility of difficulty in preferentially orienting the first thin-film piezoelectric body 72 in a predetermined plane orientation due to the influence of the ground underlying the first orientation control layer 76 is low. Therefore, the first orientation control layer 76 may lack self-orientation property.

A composition without a perovskite structure mentioned above often does not have self-orientation property. Therefore, the first orientation control layer 76 may contain a material having a perovskite structure or may contain no material having a perovskite structure.

In a case where the first orientation control layer 76 does not have self-orientation property, for example, the first orientation control layer 76 is a non-oxide containing Ti. Specifically, for example, the first orientation control layer 76 has a structure of a single crystal of Ti. If the first orientation control layer 76 is a non-oxide containing Ti, as compared with a case of having a perovskite structure, the manufacturing of the first orientation control layer 76 is easier.

For example, in a case where the first thin-film piezoelectric body 72 is formed of a material that contains lead such as PZT, the first thin-film piezoelectric body 72 is formed on a layer formed of a single crystal of Ti in the manufacturing of the first orientation control layer 76. The single crystal of Ti reacts with the ingredient such as lead contained in the first thin-film piezoelectric body 72 to form PbTiOx, and crystal growth of the first thin-film piezoelectric body 72 occurs using it as a nucleus. At this time, PbTiOx serving as the crystal nucleus orients the first thin-film piezoelectric body 72 into a predetermined plane orientation, specifically, in the (100) plane. In this case, the first orientation control layer 76 produced finally includes a layer formed of PbTiOx.

In a case where the first orientation control layer 76 has self-orientation property, an example of the material thereof is a composite oxide that has a perovskite structure including, for example, any of Ni (nickel), lanthanum (La), Bi (bismuth), lead (Pb), titanium (Ti), and iron (Fe) as its constituent element. Examples of the composite oxide that has a perovskite structure are lead titanate (PbTiO₃), lanthanum nickel oxide (LaNiO₃), PbₓBᵢ₍ₐ₋ₓ₎Fe_{y}Ti_{(b-y)}O_{z}, and PbₓFe_{y}Ti_{(1-y)}O_{z}.

Each of the first orientation control layer 76 and the second orientation control layer 77 described above may have a single-layer structure or a multiple-layer structure. Each of the first orientation control layer 76 and the second orientation control layer 77 may be made of a single kind of material or plural kinds of material.

The thickness D76 of the first orientation control layer 76 is less than the thickness D72 of the first thin-film piezoelectric body 72. The thickness D77 of the second orientation control layer 77 is less than the thickness D74 of the second thin-film piezoelectric body 74. Each of these thicknesses is an average length along the Z axis. Each of the thickness D76 and the thickness D77 is, for example, within a range from 20 nm inclusive to 200 nm inclusive, though not specifically limited thereto.

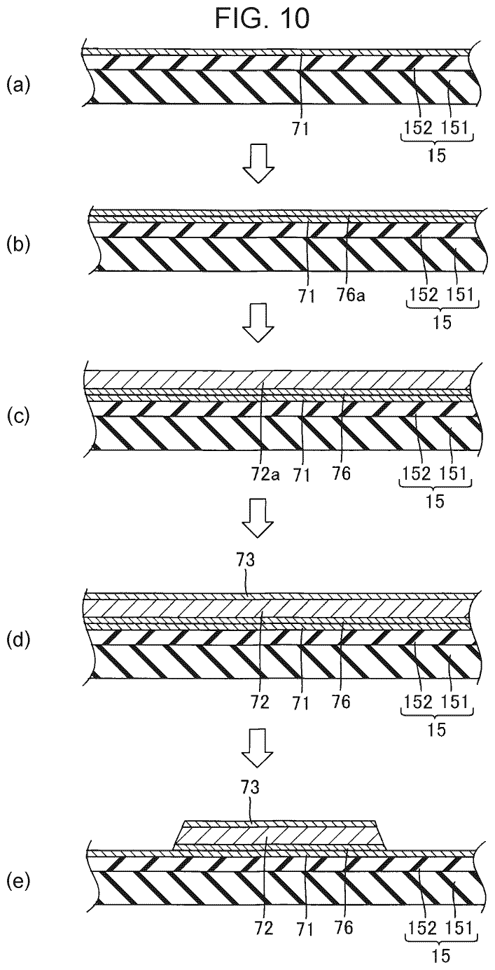

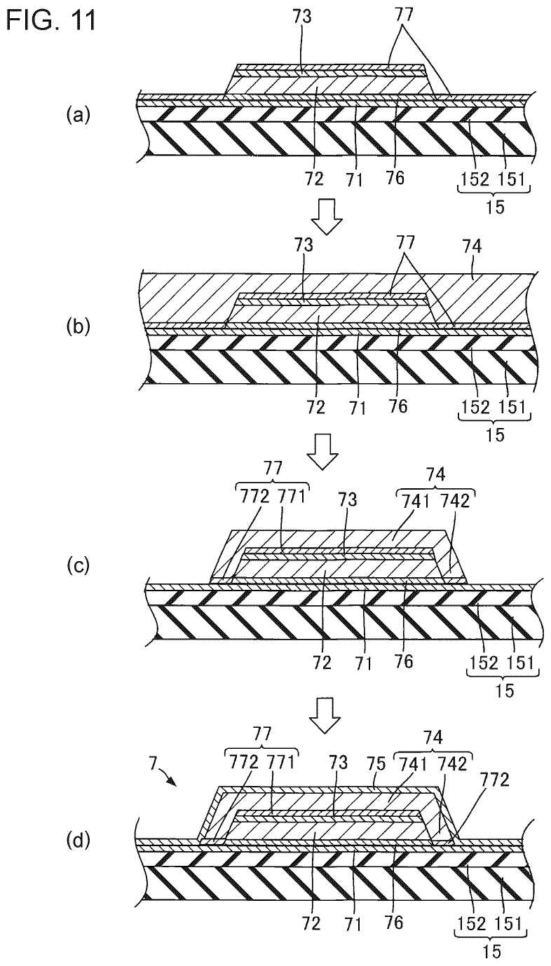

The thickness D77 of the second orientation control layer 77 may be, for example, greater than the thickness D76 of the first orientation control layer 76. An advantage of this structure is as follows. In the manufacturing of the piezoelectric element 7 to be described later, as illustrated in FIG. 10(e), the first orientation control layer 76 is also patterned in the process of etching the first thin-film piezoelectric body 72. At this time, there is a risk that the etching might proceed to an extent of going through the first orientation control layer 76 due to an etching time error or the like, resulting in eroding the first common electrode 71 away. However, since the first thin-film piezoelectric body 72 is relatively thin, etching time is short, and this is therefore less likely to happen. On the other hand, as illustrated in FIG. 11(c), the second orientation control layer 77 is patterned in the process of etching the second thin-film piezoelectric body 74. Similarly, there is a risk that the etching might proceed to an extent of going through the second orientation control layer 77 due to an etching time error or the like, resulting in eroding the first common electrode 71 away. In this respect, the second thin-film piezoelectric body 74 is thicker than the first thin-film piezoelectric body 72. Therefore, it takes longer to etch the second thin-film piezoelectric body 74 than to etch the first thin-film piezoelectric body 72, and, accordingly, the possibility of the occurrence of an etching error for the former is higher than that for the latter. Therefore, the possibility of eroding the first common electrode 71 away due to excessive etching proceeding through the second orientation control layer 77 is higher than that through the first orientation control layer 76. Configuring the second orientation control layer 77 to be thick reduces such a risk of erosion of the first common electrode 71. On the other hand, since the orientation control layer adversely acts to lower a permittivity between each electrode and each thin-film piezoelectric body when in use, it is better to configure the orientation control layer to be thin as much as possible. Therefore, the first orientation control layer 76, through which the risk of erosion of the first common electrode 71 is small by nature, is configured to be thinner than the second orientation control layer 77.

The thickness D77 of the second orientation control layer 77, when looked at from another perspective, may be less than the thickness D76 of the first orientation control layer 76. An advantage of this structure is as follows. Each of the first orientation control layer 76 and the second orientation control layer 77 is inevitably influenced by irregularities of the ground underlying it to some degree. In particular, the first orientation control layer 76 is located closer to the diaphragm 15 than the second orientation control layer 77 is, and is therefore more susceptible to the influence of irregularities of the diaphragm 15 and the influence of mixing in of elements (such as Zr) contained in the diaphragm 15. When it is desired to curb these influences, it is better to increase the thickness D76 of the first orientation control layer 76. On the other hand, since the second orientation control layer 77 is located farther from the diaphragm 15 than the first orientation control layer 76 is, these influences need not be considered so much. In addition, since increasing the thickness of the orientation control layer more than necessary will result in a decrease in permittivity as described above, it is a good choice to configure the second orientation control layer 77, which is less susceptible to the influences of irregularities and element mixing-in, to be thinner than the first orientation control layer 76.

The thickness of the first orientation control layer 76 and the thickness of the second orientation control layer 77 may be the same as each other.

### 1-5. Method of Manufacturing Piezoelectric Element 7

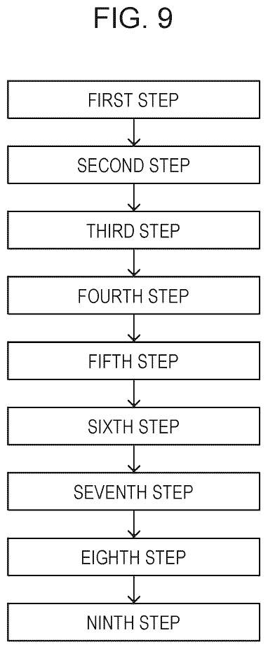

FIG. 9 is a flowchart illustrating a method of manufacturing the piezoelectric element 7 as a part of a method of manufacturing the liquid ejecting head 1. As illustrated in FIG. 9, the method of manufacturing the piezoelectric element 7 as a part of the method of manufacturing the liquid ejecting head 1 includes a first step S1, a second step S2, a third step S3, a fourth step S4, a fifth step S5, a sixth step S6, a seventh step S7, an eighth step S8, and a ninth step S9. These steps are executed in this order.

Each of FIGS. 10 and 11 is a diagram for explaining the method of manufacturing the piezoelectric element 7 illustrated in FIG. 9. FIG. 10(a) is a diagram for explaining the first step S1. In the first step S1, the first common electrode 71 is formed on the diaphragm 15. The first common electrode 71 is formed by means of, for example, a known film-forming technique such as a vapor deposition method, a sputtering method, etc. and a known processing technique using photolithography and etching, etc.

FIG. 10(b) is a diagram for explaining the second step S2. In the second step S2, the first orientation control layer 76 is formed on the first common electrode 71. The first orientation control layer 76 is formed by means of, for example, a known film-forming technique such as a vapor deposition method, a sputtering method, etc.

FIG. 10(c) is a diagram for explaining the third step S3. In the third step S3, the first thin-film piezoelectric body 72 is formed on the first orientation control layer 76. The first thin-film piezoelectric body 72 is formed by, for example, forming a precursor layer of the first thin-film piezoelectric body 72 using a sol-gel method and then by sintering the precursor layer for crystallization. A sputtering method may be used for forming the first thin-film piezoelectric body 72. However, if a sol-gel method is used, it is possible to form the first thin-film piezoelectric body 72 of 2 μm or less, or even 1 μm or less, well.

FIG. 10(d) is a diagram for explaining the fourth step S4. In the fourth step S4, the individual electrode 73 is formed on the first thin-film piezoelectric body 72. The individual electrode 73 is formed by means of, for example, a known film-forming technique such as a vapor deposition method, a sputtering method, etc.

FIG. 10(e) is a diagram for explaining the fifth step S5. In the fifth step S5, the individual electrode 73, the first thin-film piezoelectric body 72, and the first orientation control layer 76 are patterned. The patterning of them is performed by means of a known processing technique using etching, etc.

FIG. 11(a) is a diagram for explaining the sixth step S6. In the sixth step S6, the second orientation control layer 77 is formed on the individual electrode 73. The second orientation control layer 77 is formed by means of, for example, a known film-forming technique such as a vapor deposition method, a sputtering method, etc. The second orientation control layer 77 includes a portion formed on the first common electrode 71 in addition to a portion formed on the individual electrode 73.

FIG. 11(b) is a diagram for explaining the seventh step S7. In the seventh step S7, the second thin-film piezoelectric body 74 is formed on the second orientation control layer 77. The second thin-film piezoelectric body 74 is formed by, for example, forming a precursor layer of the second thin-film piezoelectric body 74 using a sol-gel method and then by sintering the precursor layer for crystallization. A sputtering method may be used for forming the second thin-film piezoelectric body 74. However, if a sol-gel method is used, it is possible to form the second thin-film piezoelectric body 74 of 2 μm or less, or even 1 μm or less, well.

FIG. 11(c) is a diagram for explaining the eighth step S8. In the eighth step S8, the second thin-film piezoelectric body 74 and the second orientation control layer 77 are patterned. The patterning of them is performed by means of a known processing technique using etching, etc. In this etching, the etching depth of the active portion 741 and the etching depth of the inactive portion 742 are different from each other. Through this etching, the first portion 771 and the second portion 772 of the second orientation control layer 77 are formed.

FIG. 11(d) is a diagram for explaining the ninth step S9. In the ninth step S9, the second common electrode 75 is formed in such a way as to cover the second thin-film piezoelectric body 74. For example, a known film-forming technique such as a vapor deposition method, a sputtering method, etc. and a known processing technique using photolithography and etching, etc. are used.

The piezoelectric element 7 of the liquid ejecting head 1 is manufactured using the method described above. With this method, it is possible to manufacture the piezoelectric element 7 easily with high precision. Moreover, according to this method, the first thin-film piezoelectric body 72 is orientation-controlled by the first orientation control layer 76 by being formed on the first orientation control layer 76, and the second thin-film piezoelectric body 74 is orientation-controlled by the second orientation control layer 77 by being formed on the second orientation control layer 77. For this reason, it is possible to design the properties of the first thin-film piezoelectric body 72 and the second thin-film piezoelectric body 74 to be desired values respectively and, therefore, it is possible to obtain the piezoelectric element 7 that has desired piezoelectric characteristics.

In the sixth step S6 mentioned above, the second orientation control layer 77 is formed not only on the individual electrode 73 but also on the first common electrode 71. Therefore, it is possible to reduce an orientation difference inside the second thin-film piezoelectric body 74. Specifically, it is possible to reduce an orientation difference between the active portion 741 and the inactive portion 742. For this reason, it is possible to make the second thin-film piezoelectric body 74 less susceptible to stress fracture and, therefore, cracking does not occur easily in the second thin-film piezoelectric body 74, resulting in an improvement in reliability of the piezoelectric element 7.

The following configuration may be adopted. The second thin-film piezoelectric body 74 is located farther from the neutral axis A1 than the first thin-film piezoelectric body 72 is. Therefore, the distortion of the second thin-film piezoelectric body 74 itself could be large, and thus there is a risk of a significant damage to the second thin-film piezoelectric body 74. On the other hand, the distance to the neutral axis A1 from the first thin-film piezoelectric body 72 is not so great, as compared with the second thin-film piezoelectric body 74. For this reason, the first thin-film piezoelectric body 72 is not so much susceptible to distortion, unlike the second thin-film piezoelectric body 74. Therefore, ejection characteristics can be improved as much as possible by configuring the second thin-film piezoelectric body 74 to be relatively thin for the purpose of damage suppression and configuring the first thin-film piezoelectric body 72, which is less susceptible to damage, to be relatively thick. As described here, the first thin-film piezoelectric body 72 may be configured to be thicker than the second thin-film piezoelectric body 74.

The following configuration may be adopted. The generative force of each thin-film piezoelectric body increases as the Young's modulus of the thin-film piezoelectric body increases. Therefore, also in a structure in which a plurality of thin-film piezoelectric bodies is stacked as in the present embodiment, in order to enhance ejection characteristics as much as possible by increasing the displacement amount of the piezoelectric element 7, it is preferable to increase the Young's modulus of each of the first thin-film piezoelectric body 72 and the second thin-film piezoelectric body 74. However, there is a possibility that increasing the Young's modulus of the second thin-film piezoelectric body 74 might result in a problem. In the manufacturing of the piezoelectric element 7, layer forming is performed sequentially from lower layers toward upper layers, and, after the second thin-film piezoelectric body 74 is formed, the second common electrode 75 and various kinds of wiring are formed thereon. In this forming, processing such as, for example, etching is performed. There is a risk that the second thin-film piezoelectric body 74 might incur a film-forming damage due to the influence of this processing by etching when the second common electrode 75 and various kinds of wiring are formed. The greater the Young's modulus is, the severer the film-forming damage is. That is, the stiffer the film is, the severer the film-forming damage is. With this considered, though it is better to increase the Young's modulus of the second thin-film piezoelectric body 74 from the viewpoint of ejection characteristics, given the risk of the film-forming damage, it is difficult to increase the Young's modulus of the second thin-film piezoelectric body 74 so much. On the other hand, at the first thin-film piezoelectric body 72, the influence on the film-forming damage is small. Therefore, in the present embodiment, the Young's modulus of the first thin-film piezoelectric body 72 is increased to compensate for the difficulty in increasing the Young's modulus of the second thin-film piezoelectric body 74, thereby guaranteeing the ejection characteristics of the piezoelectric element 7 as a whole. As described here, the Young's modulus of the first thin-film piezoelectric body 72 may be set to be greater than the Young's modulus of the second thin-film piezoelectric body 74.

From another perspective, the following configuration may be adopted. The Young's modulus of the first thin-film piezoelectric body 72 may be set to be less than the Young's modulus of the second thin-film piezoelectric body 74, though this is limited to a case where the above-described possibility of the occurrence of the film-forming damage is not considered. Even when the generative force of the first thin-film piezoelectric body 72 and the generative force of the second thin-film piezoelectric body 74 are the same as each other, the farther they are from the neutral axis A1, the greater the moment and, thus, the greater the contribution to ejection characteristics. Therefore, in order to increase the ejection characteristics as much as possible, with regard to the second thin-film piezoelectric body 74, it is better to increase the Young's modulus. On the other hand, also with regard to the first thin-film piezoelectric body 72, in order to improve the ejection efficiency as much as possible, it is better to increase the Young's modulus, though its contribution is small. However, if the Young's modulus of the first thin-film piezoelectric body 72 is increased similarly to the second thin-film piezoelectric body 74, there is a possibility that a problem might arise in ejection characteristics, especially in high-frequency driving. When ink is ejected successively, if the next ejection is performed in a state in which residual vibration inside the pressure compartment C due to the previous ejection remains, the residual vibration causes a deviation in characteristics in the next ejection. If the Young's modulus of the first thin-film piezoelectric body 72 is small, its softness absorbs the pressure of the residual vibration smoothly. Therefore, a deviation in characteristics due to successive ejection is unlikely to occur. If the Young's modulus of the first thin-film piezoelectric body 72 is large, the pressure of the residual vibration at the time of the previous ejection is not absorbed enough. Therefore, there is a risk that a deviation in characteristics might occur. As a matter of course, it is possible to better perform this pressure absorption of the residual vibration at the portion where the residual vibration occurs, that is, at the portion located closer to the pressure compartment C. Therefore, reducing the Young's modulus of the first thin-film piezoelectric body 72, which is located closer to the pressure compartment C, results in suppressing the residual vibration well. With this considered, it is also effective to set the Young's modulus of the first thin-film piezoelectric body 72 to be less than the Young's modulus of the second thin-film piezoelectric body 74.

### 2. Variation Examples

The embodiments described as examples above can be modified in various ways. Some specific examples of modification that can be applied to the embodiments described above are described below.

“Liquid ejecting head” may be a so-called circulation-type head that has a circulatory flow passage.

“Liquid ejecting apparatus” can be applied to not only print-only machines but also various kinds of equipment such as facsimiles and copiers, etc. The scope of use of the liquid ejecting apparatus is not limited to printing. For example, a liquid ejecting apparatus that ejects a colorant solution can be used as an apparatus for manufacturing a color filter of a display device such as a liquid crystal display panel. A liquid ejecting apparatus that ejects a solution of a conductive material can be used as a manufacturing apparatus for forming wiring lines and electrodes of a wiring substrate. A liquid ejecting apparatus that ejects a solution of a living organic material can be used as a manufacturing apparatus for, for example, production of biochips.

Although the present disclosure has been presented above on the basis of some preferred embodiments, the scope of the present disclosure shall not be construed to be limited to the foregoing embodiments. The structure of each part of the present disclosure can be replaced with an arbitrary structure that fulfills the same functions as those of the foregoing embodiments or similar thereto. Any arbitrary structure may be added thereto.

What is claimed is:

1. A liquid ejecting head, comprising:
a pressure compartment substrate in which a plurality of pressure compartments is provided;
a diaphragm;
a first common electrode which is provided in common to the plurality of pressure compartments and to which a reference voltage is applied, the reference voltage being a voltage that does not vary as time progresses;
a first thin-film piezoelectric body;
an individual electrode which is provided individually for each of the plurality of pressure compartments and to which a drive voltage is applied, the drive voltage being a voltage that varies as time progresses;
a second thin-film piezoelectric body; and
a second common electrode which is provided in common to the plurality of pressure compartments and to which the reference voltage is applied, wherein the pressure compartment substrate, the diaphragm, the first common electrode, the first thin-film piezoelectric body, the individual electrode, the second thin-film piezoelectric body, and the second common electrode are stacked in this order from a lower side toward an upper side, and
a second orientation control layer for controlling an orientation of the second thin-film piezoelectric body and having a property of self-orienting itself in a predetermined plane orientation is provided between the second thin-film piezoelectric body and the individual electrode.

2. The liquid ejecting head according to claim 1, wherein
the second orientation control layer is self-oriented in a (100) plane.

3. The liquid ejecting head according to claim 1, wherein
the individual electrode is preferentially oriented in a (111) plane.

4. The liquid ejecting head according to claim 3, wherein
the first thin-film piezoelectric body is preferentially oriented in a (100) plane.

5. The liquid ejecting head according to claim 1, wherein
the second orientation control layer is a composite oxide containing Bi, Fe, Ti, Pb and having a perovskite structure.

6. The liquid ejecting head according to claim 1, wherein
the second orientation control layer is a composite oxide containing Fe, Ti, Pb and having a perovskite structure.

7. The liquid ejecting head according to claim 1, wherein
the second orientation control layer is a composite oxide containing La, Ni and having a perovskite structure.

8. The liquid ejecting head according to claim 1, wherein
a first orientation control layer for controlling an orientation of the first thin-film piezoelectric body and having a property of not self-orienting itself in a predetermined plane orientation is provided between the first thin-film piezoelectric body and the first common electrode.

9. The liquid ejecting head according to claim 8, wherein
the first orientation control layer does not have a perovskite structure.

10. The liquid ejecting head according to claim 8, wherein
the first orientation control layer is a non-oxide containing Ti.

11. A liquid ejecting head, comprising:
a pressure compartment substrate in which a plurality of pressure compartments is provided;
a diaphragm;
a first common electrode which is provided in common to the plurality of pressure compartments and to which a reference voltage is applied, the reference voltage being a voltage that does not vary as time progresses;
a first thin-film piezoelectric body;
an individual electrode which is provided individually for each of the plurality of pressure compartments and to which a drive voltage is applied, the drive voltage being a voltage that varies as time progresses;
a second thin-film piezoelectric body; and
a second common electrode which is provided in common to the plurality of pressure compartments and to which the reference voltage is applied, wherein the pressure compartment substrate, the diaphragm, the first common electrode, the first thin-film piezoelectric body, the individual electrode, the second thin-film piezoelectric body, and the second common electrode are stacked in this order from a lower side toward an upper side, and
a second orientation control layer for controlling an orientation of the second thin-film piezoelectric body and being a composite oxide containing Bi, Fe, Ti, Pb and having a perovskite structure is provided between the second thin-film piezoelectric body and the individual electrode.

12. A liquid ejecting apparatus, comprising:
the liquid ejecting head according to claim 1; and
a voltage application circuit for applying the reference voltage and the drive voltage.
